(19) United States
(12) Patent Application Publication
(10) Pub. No.: US 2026/0357427 A1
(43) Pub. Date: Nov. 12, 2026

(54) METHODS TO PROVIDE VOID FREE TRENCH FILL FOR LOGIC AND MEMORY APPLICATIONS

(71) Applicant: Lam Research Corporation, Fremont, CA (US)

(72) Inventors: Tao Zhang, Tigard, OR (US); Jonathan Grant Baker, Sherwood, OR (US); Pulkit Agarwal, Beaverton, OR (US)

(21) Appl. No.: 19/485,996

(22) PCT Filed: Jun. 6, 2024
(86) PCT No.: PCT/US2024/032756

§ 371 Date: Nov. 19, 2025

Related U.S. Application Data
(60) Provisional application No. 63/507,403, filed on Jun. 9, 2023.

(51) Int. Cl. C23C 16/455; C23C 16/04; C23C 16/40; H10P 14/60

(52) U.S. Cl. CPC C23C 16/45542; C23C 16/045; C23C 16/40; C23C 16/45534; H10P 14/6336; H10P 14/6339

(57) ABSTRACT

Filling a gap with a dielectric material includes using an inhibition plasma during deposition. The inhibition plasma increases a nucleation barrier of the deposited film. The inhibition plasma selectively interacts near the top of the feature, inhibiting deposition at the top of the feature compared to the bottom of the feature, enhancing bottom-up fill.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor device fabrication processes involve formation of films including silicon-containing films such as silicon oxide or silicon nitride. Plasma enhanced atomic layer deposition (PEALD) may be used to deposit silicon-containing films. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of filling gaps in structures. In one aspect of the embodiments herein, a method of filling gaps is provided, the method including: receiving a substrate in a process chamber, the substrate having one or more structures, each structure including a gap; and performing a set of cycles of: (a) exposing the substrate to one or more precursor species; and (b) after (a), exposing the substrate to a plasma including one or more inhibition species and one or more co-reactants. In some embodiments, the one or more inhibition species inhibits an adsorption of precursor species during a subsequent cycle. In some embodiments, performing the set of cycles further includes: (c) after (b), exposing the substrate to a plasma including the one or more inhibition species without the one or more co-reactants. In some embodiments, each cycle of the set of cycles has a duration less than about 7 seconds. In some embodiments, each cycle of the set of cycles has a duration between about 2.5 seconds and about 5 seconds. In some embodiments, the set of cycles consists essentially of (a) and (b). In some embodiments, the one or more co-reactants include an oxygen-containing species. In some embodiments, the one or more inhibition species include a nitrogen-containing species. In some embodiments, the nitrogen-containing species is N₂, NH₃, or N₂O. In some embodiments, the one or more inhibition species consists of a nitrogen-containing, non-halogen containing species. In some embodiments, the one or more inhibition species inhibits near a top of the structures during (b). In some embodiments, the one or more co-reactants reacts with the one or more precursor species during (b) to form a dielectric material. In some embodiments, the dielectric material is an oxide material. In some embodiments, performing the set of cycles further includes purging the one or more precursor species from the process chamber between (a) and (b). In some embodiments, performing the set of cycles fills the one or more structures from a bottom of the gap up.

In another aspect of the embodiments herein, a system is provided the system including: a process chamber; and one or more processors and one or more memories, the one or more memories including computer-executable instructions for controlling the one or more processors for: receiving a substrate in the process chamber, the substrate having one or more structures, each structure including a gap; and performing a set of cycles of: (a) exposing the substrate to one or more precursor species; and (b) after (a), exposing the substrate to a plasma including one or more inhibition species and one or more co-reactants.

These and other features of the disclosed embodiments will be described in detail below with reference to the associated drawings.

### BRIEF DESCRIPTION OF DRAWINGS

FIG. 1 presents a flow diagram of operations for filling gaps with dielectric material.

FIG. 2 presents a flow diagram of operations for filling gaps using a combined ALD-inhibition plasma.

FIG. 3 presents a flow diagram of operations for atomic layer deposition processes.

FIGS. 4A and 4B present timing diagrams for various operations discussed herein.

FIG. 5 presents experimental data of various processes described herein.

FIGS. 6-9 are schematic diagrams of examples of process chambers for performing methods in accordance with disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to oxide films and silicon-containing films such as silicon oxide, and related systems and apparatuses. The methods described herein can be used to fill vertically oriented features formed in a substrate. Such features may be referred to as gaps, recessed features, negative features, unfilled features, or simply features. Filling such features may be referred to as gapfill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to a method of using an inhibition plasma during atomic layer deposition (ALD) of dielectric material in gaps that facilitates void-free bottom gapfill. The inhibition plasma creates a passivated surface and increases a nucleation barrier of the deposited ALD film. When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. As a result, bottom-up fill is enabled in an ALD process, which creates a more favorable sloped profile that mitigates seam effect and prevents void formation.

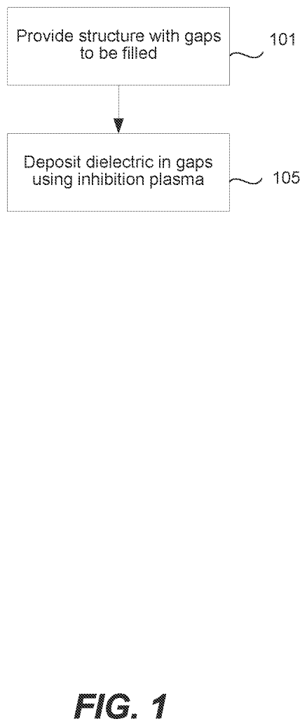

FIG. 1 is a process flow diagram that illustrates a method of filling gaps with dielectric material. The method begins with providing a structure with one or more gaps to be filled. (101). The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gapfill other substrates, such as glass, plastic, and the like, including in the fabrication of microelectromechanical (MEMS) devices.

Examples of structures include 3D NAND structures, DRAM structures, and shallow trench isolation (STI) structures. The structures include gaps with the sidewalls of the gaps formed by a material susceptible to etch. In one example, 3D NAND structure includes oxide-nitride-oxide-nitride (ONON) stacks covered with a poly Si layer. In another example, structures may include lateral/tunnel structures that extend horizontally from a common vertical trench. Other examples of sidewall materials include oxides, metals, and semiconducting materials. The methods described herein are not limited to a particular class of sidewall material and may be used to inhibit any susceptible material.

Dielectric material is deposited in the gaps using an inhibition plasma. (105). As discussed further below, this can involve ALD cycles that may simultaneously inhibit and deposit within features. In particular, an ALD cycle may be designed to expose the substrate to a co-reactant that converts silicon precursor adsorbed onto a surface of features while also exposing the substrate to an inhibitor species that inhibits deposition near the top of features.

Inhibition treatments may be performed using various species. In some embodiments, a halogen-based species may be used, such as NF₃, while in other embodiments a nitrogen-based species may be used, such as N₂. NF₃ is much more inhibitive than N₂, such that NF₃ may not be usable in some aspect ratios due to excessive inhibition that slows throughput. N₂, by contrast, is a worse inhibitor than NF₃, requiring a longer dose time to effectively inhibit, allowing it to be used in lower aspect ratios that NF₃ may over-inhibit. In addition to the depth difference in inhibition, inhibition using N₂ is also relatively short; in some embodiments only one or two cycles of ALD may be performed between inhibition plasma treatments using N₂ before an additional inhibition is performed to maintain bottom-up fill. This can significantly decrease throughput when combined with the increased time for an N₂-based inhibition plasma treatment.

Disclosed herein are processes to improve bottom-up fill using ALD and inhibition plasma treatments with nitrogen-based inhibitor species such as N₂. While N₂ is used throughout this disclosure, it should be understood that other nitrogen-based species may be used, e.g., N₂O or NH₃. The inhibition plasma treatment may be combined with a reactant plasma treatment (e.g., O₂) to simultaneously convert precursor into dielectric film and inhibit deposition near the top of features. In some embodiments, an oxygen- and nitrogen-containing plasma treatment may inhibit deposition near the top of a feature while also converting adsorbed precursor near the bottom of the feature, resulting in a bottom-up fill mechanism.

The simultaneous use of inhibition and reactant species is based on the mechanism of nitrogen-based inhibition. Inhibition of deposition in ALD-based deposition processes may use various mechanisms. One mechanism may expose the substrate to a halogen-based chemistry that preferably bonds with adsorbed precursor over an oxygen-containing co-reactant. The halogen may be preferentially bonded near the top of features. As the oxygen-containing reactant is disfavored to displace a halogen, e.g., fluorine, the oxygen-containing reactant mainly bonds near the bottom of the feature where fewer halogens are present. Thus, co-flowing a halogen-containing species with an oxygen-containing species at similar flow rates would merely inhibit oxygen-based reaction kinetics and reduce the deposition rate, which is undesirable.

Nitrogen-based inhibition uses a different mechanism than halogen-based inhibition. Nitrogen species will preferably bond with dielectric films near the top of the feature, inhibiting the adsorption of a silicon-containing precursor. During a precursor dose step fewer or no precursors adsorb near the top of the feature. As the silicon-containing precursor is not present near the top of the feature, the oxygen radicals cannot react to form silicon oxide. While this achieves a similar inhibition effect as a halogen-based inhibition plasma, a nitrogen-based inhibition plasma does not rely on competing with oxygen radicals.

Thus, this difference in mechanism allows for a nitrogen-based inhibition plasma treatment to be combined with an oxygen-containing reactant process to convert precursor into silicon oxide. As oxygen bonds are more favorable than nitrogen bonds, silicon-containing precursors near the bottom of the feature will preferably bond with oxygen radicals over nitrogen radicals. Simultaneously, the nitrogen radicals will react with silicon oxide near the top of the feature to inhibit subsequent precursor treatments from adsorbing.

The degree of inhibition may be controlled based on the duration of the nitrogen-based plasma as well as the ratio of oxygen-containing reactants to nitrogen-containing reactants. This allows for multiple inhibition blocks that vary an inhibition effective depth (IED) by controlling the parameters of the oxygen- and nitrogen-containing plasma. During design of a bottom-up fill process, multiple inhibition blocks may be planned where an inhibition plasma treatment may be changed between inhibition blocks. For example, an inhibition plasma treatment may be tuned so that the IED is closer to the bottom of the feature, e.g., 75% of the total depth of the feature is inhibited measuring from a top of the feature down. Cycles of an ALD process may then be performed to fill the bottom 25% of the feature. The inhibition plasma parameters may then be adjusted to inhibit, e.g., the top 50% of the feature (relative to the total depth and notwithstanding any fill), and then the next bottom portion of the feature is filled. An inhibition plasma may inhibit from a top of a feature to an IED, wherein the IED may vary between inhibition blocks as the feature is filled.

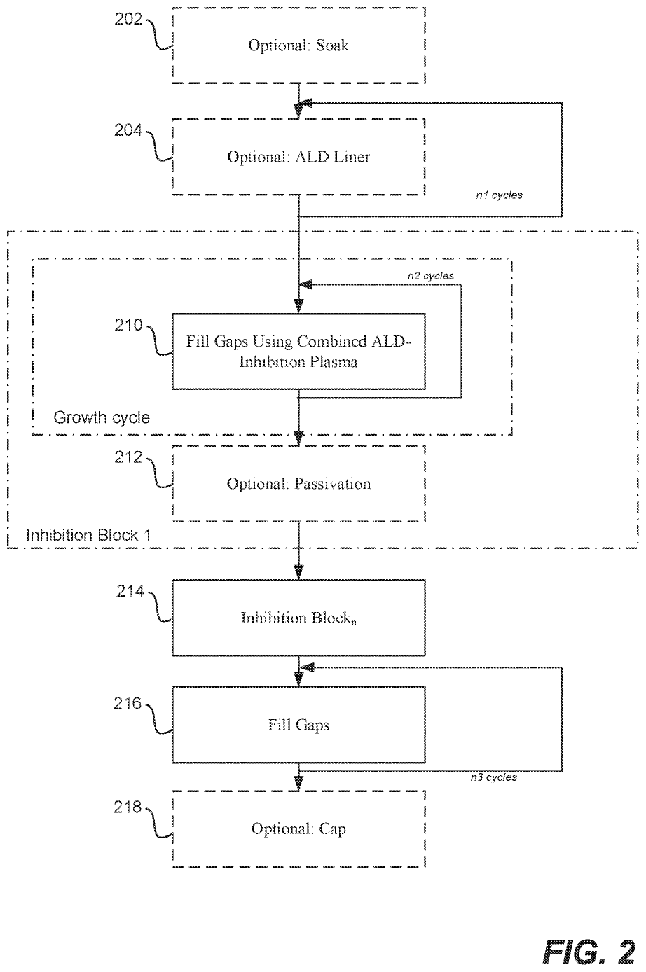

FIG. 2 shows an example of a process sequence that may be used in accordance with the disclosed embodiments. The process sequence in FIG. 2 includes treating a substrate with a combined ALD-inhibition plasma. Other operations (e.g., soak, passivation) may be omitted in certain embodiments and operations may be added in certain embodiments. In the example process sequence of FIG. 2, one or more wafers undergo gap fill. The process may begin with a soak after being provided to a deposition chamber. (202). This can be useful, for example, to remove particles or other pretreatment. Then, n1 cycles of ALD deposition of a liner are performed. (204). Further details of a liner ALD are discussed below.

After the optional liner is deposited, n inhibition blocks are performed, with the operations of the first inhibition block (n=1) shown. The first is a set of n2 cycles of combined ALD-inhibition fill. (210). In some embodiments, the inhibition plasma is generated from non-halogen containing species, including nitrogen-containing species and nitrogen-containing, non-halogen-containing species. For example, plasmas generated from molecular nitrogen (N₂), molecular hydrogen (H₂), ammonia (NH₃), N₂O, amines, diols, diamines, aminoalcohols, thiols, or combinations thereof may be used as inhibition plasmas.

When the inhibition plasma interacts with material in the feature, the material at the bottom of the feature receives less inhibition plasma treatment than material located closer to a top portion of the feature or in field because of geometrical shadowing effects. Reactant may also be co-flowed with the inhibition species and interact with adsorbed precursor to form a dielectric film. As more precursors are adsorbed near the bottom of the feature, film growth is greater at the bottom of the feature compared to the top, resulting in bottom-up fill.

As a result, deposition at the top of the feature is selectively inhibited and deposition in lower portions of the feature proceeds with less inhibition or without being inhibited. The dielectric material is deposited selectively at the bottom of the feature. A set of n2 cycles of ALD fill makes a growth cycle. The number of growth cycles in an inhibition block may depend on the re-entrancy of the feature, i.e., if it narrows at one or more points from the bottom to the top of the feature. Features that exhibit more re-entrancy may use a longer inhibition time or multiple inhibition blocks.

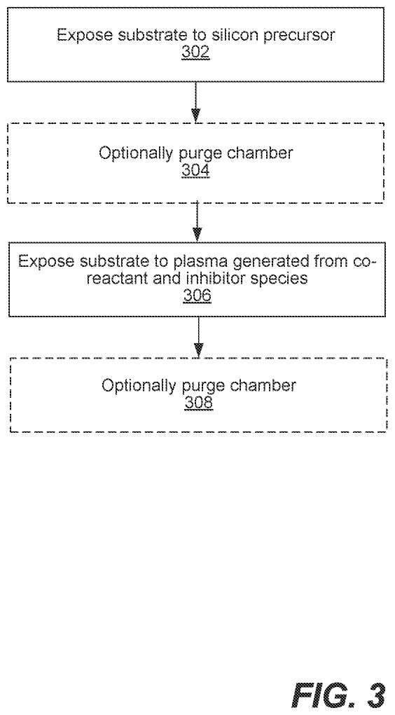

In the example of FIG. 3, the inhibition block ends with an optional passivation operation. (212). This is a surface treatment that removes residual inhibitor and can also densify the deposited film. In some embodiments, an oxygen plasma is used.

One or more additional inhibition blocks, including growth cycle and passivation, may be performed for a total of n inhibition blocks. (214). The number of inhibition blocks depends on how much material is used to fill the feature. Inhibition plasma, ALD, and passivation conditions may be changed from inhibition block to inhibition block to fill the feature. For example, a combined ALD-inhibition plasma duration may be 20 seconds until the bottom quarter of the feature is filled (inhibition block 1), then changed to 10 seconds for the middle 50% of the structure (inhibition block 2), etc. Each inhibition block may have a different IED, where process parameters for an inhibition plasma treatment for an inhibition block are changed to target a different IED. The inhibition plasma treatment may be the duration of flowing inhibitor during a combined reactant/inhibitor step as well as flowing inhibitor while igniting a plasma as part of a purge step. Each inhibition block may fill a portion of the feature below an IED of that inhibition block.

When the feature is nearly filled, inhibition may no longer be necessary, and the fill can be completed with n3 cycles of ALD fill. (216). In some embodiments, an optional cap or overburden layer of dielectric may then be deposited. (218). Plasma enhanced chemical vapor deposition (PECVD) may be used at this stage for a fast deposition.

ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations.

As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. One or more reactants, such as an oxygen-containing gas or nitrogen-containing gas, is introduced to the chamber so that some of these molecules react with the first precursor adsorbed on the surface. In some processes, the reactants react immediately with the adsorbed first precursor. In other embodiments, the reactants reacts only if a source of activation such as plasma is applied temporally. The chamber may then be evacuated again to remove unbound reactant molecules. As described above, in some embodiments the chamber may not be completely evacuated. Additional ALD cycles may be used to build film thickness.

During a combined inhibition-ALD process, the one or more reactants may include an inhibition species and a reactant species. The inhibition species may inhibit top portions of features, while the reactants may react with adsorbed precursor. As the inhibition species inhibits the adsorption of precursors, the present inhibition species exposure will cause a subsequent precursor exposure to not result in adsorbed precursor near the top of the feature. Thus, the reactant species will not react with precursors near the top of the feature as there are few to no adsorbed precursors near the top of the feature.

FIG. 3 presents a process flow diagram for a single plasma enhanced ALD cycle that may be implemented as part of operations 204, 210, and/or 216 shown in FIG. 2. In an operation 302, the substrate is exposed to a silicon-containing precursor, to adsorb the precursor onto the surface of the feature. This operation may be self-limiting. In some embodiments, the precursor adsorbs to less than all the active sites on the surface of the feature. In an operation 304, the process chamber is optionally purged to remove any unadsorbed silicon-containing precursors. In an operation 306, the substrate is exposed to a plasma generated from an inhibition species and a co-reactant. Example inhibition species and reactants include N₂, O₂, and/or N₂O to form a silicon oxide layer or silicon oxynitride layer, N₂ or NH₃ to form a silicon nitride layer, methane (CH₄) to generate a silicon carbide layer etc. In operation 308, the process chamber is optionally purged to remove byproducts from the reaction between the silicon-containing precursor and the oxidant. Operations 302 through 308 repeated for a number of cycles to deposit the silicon-containing layer to a desired thickness in the feature.

It should be noted that the processes described herein are not limited to a particular reaction mechanism. Thus, the process described with respect to FIG. 3 includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

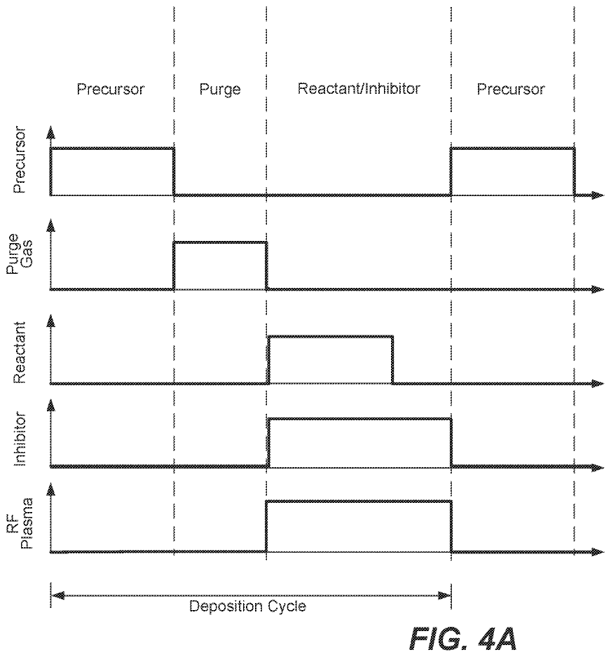

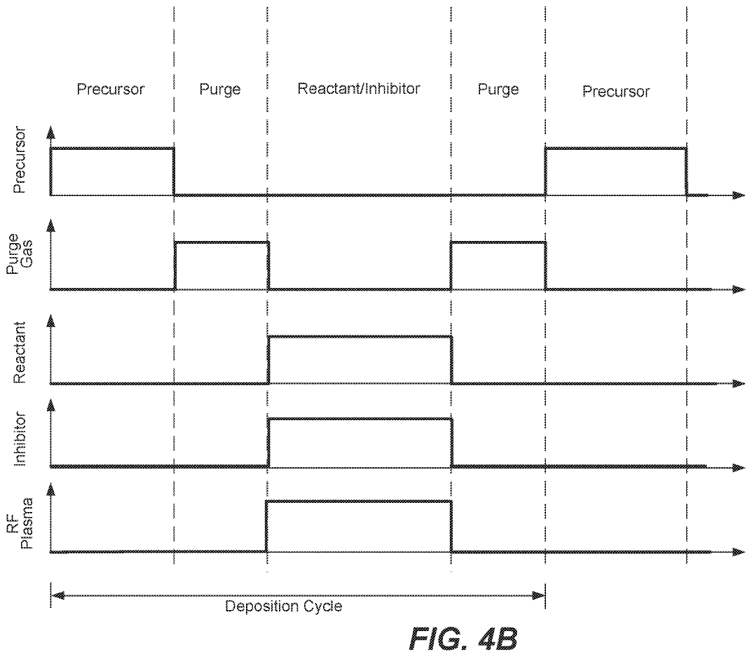

FIGS. 4A and 4B illustrate timing diagrams for a combined inhibition-ALD cycle as described herein. The steps shown in FIGS. 4A and 4B may generally correlate with the steps described above in relation to FIG. 3. In FIG. 4A, precursor, purge gas, oxidizer, inhibitor, and RF plasma are shown for a 3 step cycle of precursor exposure, purge, and reactant/inhibitor exposure. During the precursor exposure precursor gas is flowed to a process chamber. Precursor species may adsorb onto surfaces of a substrate as described herein, similar to step 302 above. During the purge step the flow of precursor is removed, while the flow of purge gas is increased to remove any unadsorbed precursors.

During the reactant/inhibitor step reactant and inhibitor are flowed into the process chamber while a plasma is ignited. The reactant will react with adsorbed precursors to form a dielectric film near the bottom of the feature. The inhibitor species will inhibit near the top of the features. Notably, during the reactant/inhibitor step the flow of reactant may be stopped prior to the end of the step. This results in only inhibitor species flowing during the last portion of the reactant/inhibitor step. By removing the flow of reactant species the inhibitor species may act as a purge gas while inhibiting, evacuating any reactant species from the process chamber prior to a subsequent precursor step.

While FIG. 4A does not show the RF plasma changing during the reactant/inhibitor step after the flow of reactant is stopped, the plasma properties may change after the flow of reactant is stopped. For example, the power of the plasma may change. Furthermore, a flow rate of inhibitor species may change.

FIG. 4B presents a similar timing diagram as FIG. 4A. However, in FIG. 4B, the flow of reactant is not stopped during the reactant/inhibitor step, and instead a separate purge step is performed prior to a subsequent precursor dose step. The separate purge step assists in evacuating any reactant in the process chamber prior to a subsequent precursor dose step.

Combining an inhibition plasma with a reactant exposure process as described herein may improve throughput by reducing the duration of a complete cycle of inhibition and ALD cycles. A single deposition cycle of a combined ALD-Inhibition plasma process, such as those shown in FIGS. 4A and 4B, may be performed in about 2.5 to about 5.5 seconds, less than about 5 seconds, less than about 6 seconds, or less than about 7 seconds. Previous growth cycles, which perform a separate inhibition plasma treatment, may take more than about 7 seconds to perform a single cycle. In some embodiments, processes disclosed herein may reduce the time to deposit films by more than 50% compared to prior art methods using a separate inhibition treatment. This process may be particularly effective when using a non-halogen containing-inhibition species. As non-halogen-containing inhibition species may be used for an inhibition treatment that must be performed after one or two ALD cycles, combining the inhibition treatment with the ALD cycle as described herein may significantly increase throughput by eliminating a separate inhibition treatment as part of each ALD cycle.

In some embodiments, a combined ALD-inhibition may be performed at a pressure of more than about 1 Torr, at least about 10 Torr, at least about 15 Torr, at least about 20 Torr, between about 10 Torr and about 30 Torr, or between about 15 Torr and 30 Torr.

The duration of a combined ALD-inhibition plasma treatment may be between about 0.3 seconds and about 60 seconds, between about 0.3 seconds and about 5 seconds, at least about 0.3 seconds, at least about 1 second, at least about 5 seconds. at least about 10 seconds, at least about 20 seconds, or at least about 30 seconds.

Combined ALD-inhibition treatment may be used for various aspect ratios and structure depths. In some embodiments, inhibition plasma treatment may be used for low aspect ratio structures. A low aspect ratio structure may have an aspect ratio between about 3:1 and about 7:1, less than about 10:1, between about 3:1 and about 10:1, between about 3:1 and about 15:1, or less than about 15:1. A low aspect ratio structure may have a depth of at least about 100 nm, at least about 1 μm, at least about 2 μm, or at least about 3 μm.

In some embodiments, IED may be characterized by a percentage, e.g., 30% IED refers to an inhibition effective depth of 30% of the total depth of a feature. Thus, if a feature has a depth of 1 μm, a 30% IED means deposition would be inhibited along the sidewall surface of the feature that is within 300 nm from the top of the feature, with the remaining depth not being inhibited. In some embodiments, the IED of an inhibition plasma treatment according to embodiments described herein may be about 20%, about 30%, about 40%, about 50%, about 60%, or about 70%.

In some embodiments, inhibition species and reactant species may be co-flowed. A ratio of inhibition species and reactant species may be between about 10:1 and about 1:10. A flow of inhibition species and reactant species may vary between about 0.5 and about 5 slm, including inhibition species and reactants such as N₂, NH₃, N₂O, H₂, and O₂.

In some embodiments the ratio of inhibition species to inert gas may be about 1:5, about 1:10, between about 1:10 and about 1:20, between about 1:100 and about 1:500, or between about 1:5 and about 1:5000. In some embodiments, the flow of non-halogen-containing species, such as N₂, may be between about 0.5 slm and about 10 slm. In some embodiments, an inert gas may be co-flowed with the species used for inhibition. Inert gases may include helium, argon, xenon, or other gases that are non-reactive with the other species in the gas or surfaces of the substrate. The flow of inert gases, when used, may be between about 3.5 and about 15 slm or between about 10 slm and about 40 slm. In some embodiments, oxygen- or hydrogen-containing species may be co-flowed with the species used for inhibition. If the species used for inhibition includes a nitrogen atom, the nitrogen atom may react with silicon-containing precursors or the silicon film to form silicon nitride. Adding oxygen- or hydrogen-containing species may inhibit conversion of silicon oxide or silicon to silicon nitride, respectively. In some embodiments, co-flows of oxygen- or hydrogen-containing species may be at least about 100 sccm, or between about 0 and about 5 slm.

In various embodiments, the plasma is an in-situ plasma, such that the plasma is formed directly above the substrate surface in the station. Example power per substrate areas for an in-situ plasma are between about 0.2122 W/cm² and about 2.122 W/cm² in some embodiments. In some embodiments a dual-source RF power is used, having a high frequency (HF) component and a low frequency (LF) component. For example, the HF power may range from about 500 W to about 6000 W for a chamber processing four 300 mm wafers. In some embodiments, the HF power may be between about 2500 W and about 6000 W for four 300 mm wafers. In some embodiments, the LF power may be between about 0 W and about 4000 W. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

Various ratios and flow rates of gases, as well as various LF and HF powers may be used to perform embodiments described herein. Generally, higher HF power, higher H₂/NH₃, and lower oxidizer when coflowing may have a stronger inhibition effect.

For depositing silico-containing films, one or more silicon-containing precursors may be used. In some examples, silicon-containing precursors can include silanes (e.g., SiH₄), polysilanes (H₃Si—(SiH₂)ₙ—SiH₃) where n≥1, organosilanes, halogenated silanes, aminosilanes, alkoxysilanes, and the like. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino- 1,1-dimethyl disiloxane, 1-N-methylethylamino-1,1-dimethyl disiloxane, 1-N methylpropylamino-1,1-dimethyl disiloxane, 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

### EXAMPLE

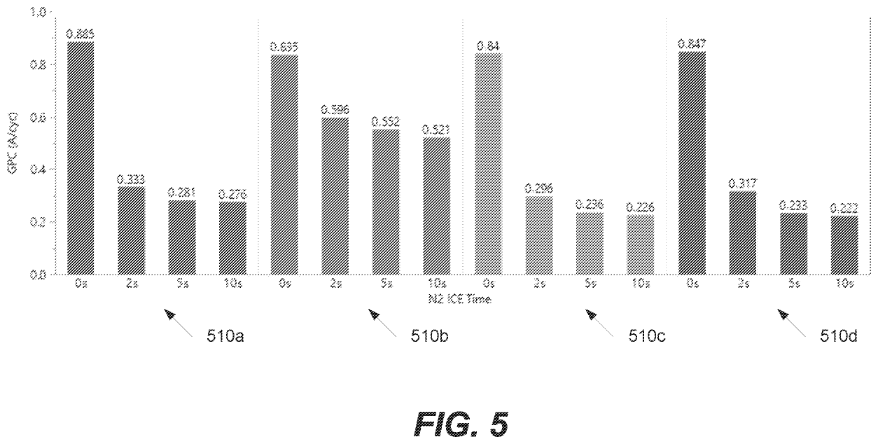

FIG. 5 presents an example of growths per cycle (GPC) as a function of N₂ inhibition time for various processes. Chart 510a represents performing an inhibition plasma treatment as a separate process prior to performing an ALD cycle to deposit dielectric material. Chart 510b represents performing an inhibition plasma treatment after a precursor dose step and before a reactant plasma exposure step. Chart 510c represents performing an inhibition plasma treatment after a reactant plasma exposure step and before a precursor dose step. Chart 510d represents performing an inhibition plasma treatment simultaneously with a reactant plasma exposure step. Lower numbers correlate with a stronger inhibition effect, which is preferable. The GPC rate for chart 510d for each duration of N₂ exposure time is slightly lower than the corresponding GPC rate in chart 510a and 510b, and is nearly the same as chart 510c. While not illustrated in FIG. 5, the process correlating to chart 510d has the shortest cycle, as the inhibition plasma treatment is performed simultaneously with the reactant plasma exposure step. Thus, performing a combined inhibition-ALD process as described herein may have similar inhibition as a process with a separate, time-consuming inhibition step.

### Apparatus

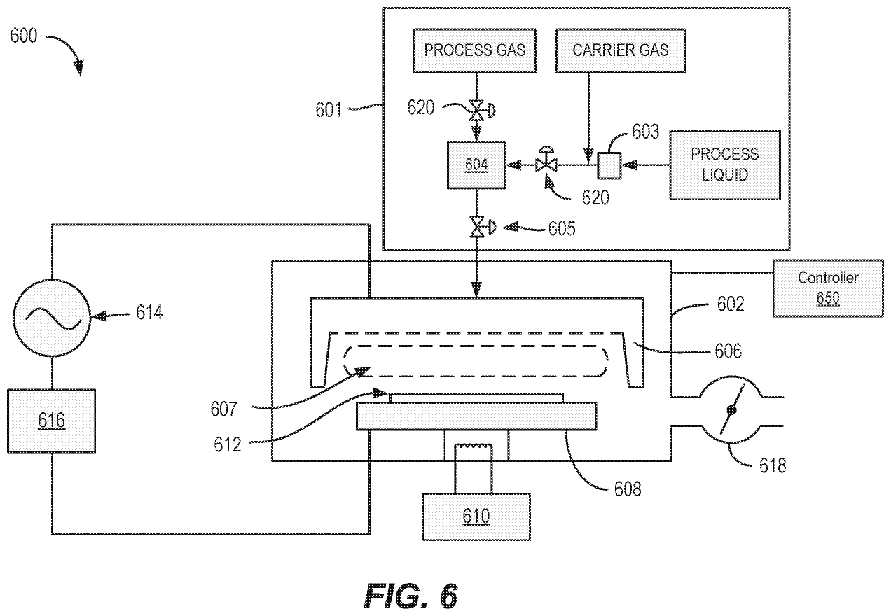

FIG. 6 schematically shows an embodiment of a process station 600 that may be used to deposit material using atomic layer deposition (ALD) and/or chemical vapor deposition (CVD), either of which may be plasma enhanced. For simplicity, the process station 600 is depicted as a standalone process station having a process chamber body 602 for maintaining a low-pressure environment. However, it will be appreciated that a plurality of process stations 600 may be included in a common process tool environment. Further, it will be appreciated that, in some embodiments, one or more hardware parameters of process station 600, including those discussed in detail below, may be adjusted programmatically by one or more computer controllers 650.

Process station 600 fluidly communicates with reactant delivery system 601 for delivering process gases to a distribution showerhead 606. Reactant delivery system 601 includes a mixing vessel 604 for blending and/or conditioning process gases for delivery to showerhead 606. One or more mixing vessel inlet valves 620 may control introduction of process gases to mixing vessel 604. Similarly, a showerhead inlet valve 605 may control introduction of process gasses to the showerhead 606. In some embodiments, an inhibitor or other gas may be directly delivered to the chamber body 602. One or more mixing vessel inlet valves 620 may control introduction of process gases to mixing vessel 604. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 6 includes a vaporization point 603 for vaporizing liquid reactant to be supplied to mixing vessel 604. In some embodiments, vaporization point 603 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100 °C to approximately 150 °C at mixing vessel 604.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller (LFC) upstream of vaporization point 603 may be provided for controlling a mass flow of liquid for vaporization and delivery to process station 600. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 606 distributes process gases toward substrate 612. In the embodiment shown in FIG. 6, substrate 612 is located beneath showerhead 606, and is shown resting on a pedestal 608. It will be appreciated that showerhead 606 may have any suitable shape, and may have any suitable number and arrangement of ports for distributing processes gases to substrate 612.

In some embodiments, a microvolume 607 is located beneath showerhead 606. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 608 may be raised or lowered to expose substrate 612 to microvolume 607 and/or to vary a volume of microvolume 607. For example, in a substrate transfer phase, pedestal 608 may be lowered to allow substrate 612 to be loaded onto pedestal 608. During a deposition process phase, pedestal 608 may be raised to position substrate 612 within microvolume 607. In some embodiments, microvolume 607 may completely enclose substrate 612 as well as a portion of pedestal 608 to create a region of high flow impedance during a deposition process.

Optionally, pedestal 608 may be lowered and/or raised during portions the deposition process to modulate process pressure, reactant concentration, etc., within microvolume 607. In one scenario where process chamber body 602 remains at a base pressure during the deposition process, lowering pedestal 608 may allow microvolume 607 to be evacuated. Example ratios of microvolume to process chamber volume include, but are not limited to, volume ratios between 1:600 and 1:10. It will be appreciated that, in some embodiments, pedestal height may be adjusted programmatically by a suitable computer controller.

In another scenario, adjusting a height of pedestal 608 may allow a plasma density to be varied during plasma activation and/or treatment cycles included in the deposition process. At the conclusion of the deposition process phase, pedestal 608 may be lowered during another substrate transfer phase to allow removal of substrate 612 from pedestal 608.

While the example microvolume variations described herein refer to a height-adjustable pedestal, it will be appreciated that, in some embodiments, a position of showerhead 606 may be adjusted relative to pedestal 608 to vary a volume of microvolume 607. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers.

Returning to the embodiment shown in FIG. 6, showerhead 606 and pedestal 608 electrically communicate with RF power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are included above. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 608 may be temperature controlled via heater 610. Further, in some embodiments, pressure control for deposition process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to process station 600.

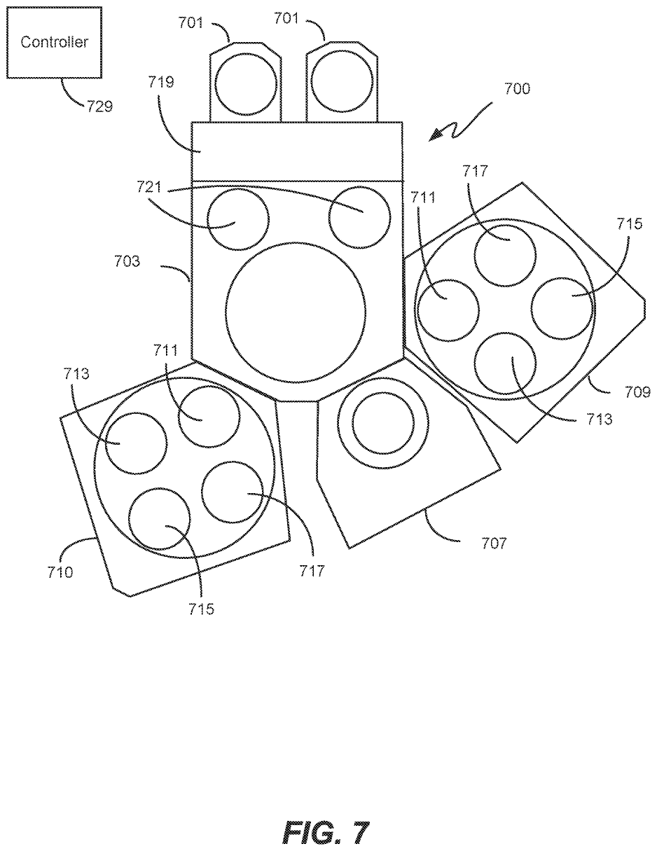

FIG. 7 is a block diagram of a processing system suitable for conducting thin film deposition processes in accordance with certain embodiments. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to certain embodiments. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the inhibition species flow, RF power, hydrogen flow, oxygen flow, and silicon-containing precursor flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 729. The signals for controlling the process are output on the analog and digital output connections of the deposition apparatus 700.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as controller 650 or 729, is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

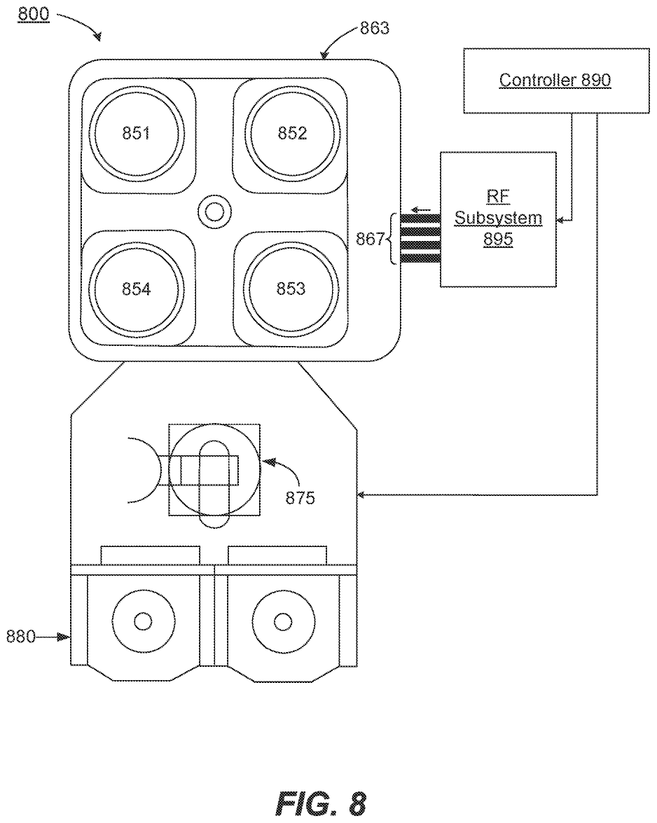

It may be appreciated that a plurality of process stations may be included in a multi-station processing tool environment, such as shown in FIG. 8, which depicts a schematic view of an embodiment of a multi-station processing tool. Processing apparatus 800 employs an integrated circuit fabrication chamber 863 that includes multiple fabrication process stations, each of which may be used to perform processing operations on a substrate held in a wafer holder, such as a pedestal, at a particular process station. In the embodiment of FIG. 8, the integrated circuit fabrication chamber 863 is shown having four process stations 851, 852, 853, and 854. Other similar multi-station processing apparatuses may have more or fewer process stations depending on the implementation and, for example, a desired level of parallel wafer processing, size/space constraints, cost constraints, etc. Also shown in FIG. 8 is substrate handler robot 875, which may operate under the control of system controller 890, configured to move substrates from a wafer cassette (not shown in FIG. 8) from loading port 880 and into integrated circuit fabrication chamber 863, and onto one of process stations 851, 852, 853, and 854.

FIG. 8 also depicts an embodiment of a system controller 890 employed to control process conditions and hardware states of processing apparatus 800. System controller 890 may include one or more memory devices, one or more mass storage devices, and one or more processors, as described herein.

RF subsystem 895 may generate and convey RF power to integrated circuit fabrication chamber 863 via radio frequency input ports 867. In particular embodiments, integrated circuit fabrication chamber 863 may comprise input ports in addition to radio frequency input ports 867 (additional input ports not shown in FIG. 8). Accordingly, integrated circuit fabrication chamber 863 may utilize 8 RF input ports. In particular embodiments, process stations 851-854 of integrated circuit fabrication chamber 863 may each utilize first and second input ports in which a first input port may convey a signal having a first frequency and in which a second input port may convey a signal having a second frequency. Use of dual frequencies may bring about enhanced plasma characteristics.

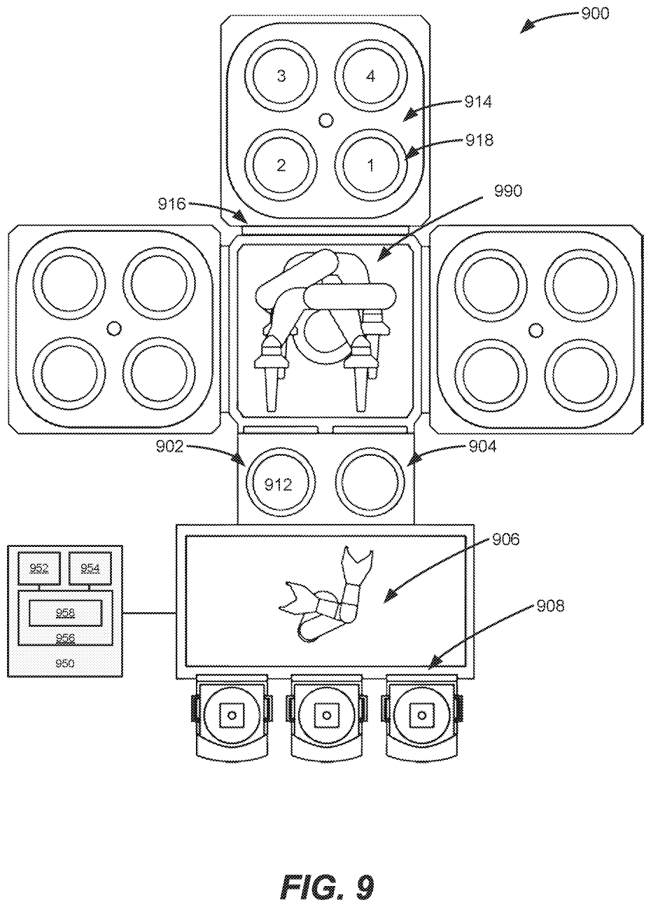

As described above, one or more process stations may be included in a multi-station processing tool. FIG. 9 shows a schematic view of an embodiment of a multi-station processing tool 900 with an inbound load lock 902 and an outbound load lock 904, either or both of which may comprise a remote plasma source. A robot 906, at atmospheric pressure, is configured to move substrates or wafers from a cassette loaded through a pod 908 into inbound load lock 902 via an atmospheric port. A substrate is placed by the robot 906 on a pedestal 912 in the inbound load lock 902, the atmospheric port is closed, and the load lock is pumped down. Where the inbound load lock 902 comprises a remote plasma source, the substrate may be exposed to a remote plasma treatment in the load lock prior to being introduced into a processing chamber 914. Further, the substrate also may be heated in the inbound load lock 902 as well, for example, to remove moisture and adsorbed gases. Next, a chamber transport port 916 to processing chamber 914 is opened, and another robot 990 places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 906 on the pedestal 912.

The depicted processing chamber 914 comprises four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between an inhibition plasma, passivation plasma, ALD and/or PEALD process mode. Additionally or alternatively, in some embodiments, processing chamber 914 may include one or more matched pairs of ALD and plasma-enhanced ALD process stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an embodiment of a wafer handling system 990 for transferring substrates within processing chamber 914. In some embodiments, wafer handling system 990 may transfer substrates between various process stations and/or between a process station and a load lock. It will be appreciated that any suitable wafer handling system may be employed. Non-limiting examples include wafer carousels and wafer handling robots. FIG. 8 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc. In some embodiments, system controller 950 includes machine-readable instructions for performing operations such as those described herein.

In some embodiments, system controller 950 controls the activities of process tool 900. System controller 950 executes system control software 958 stored in mass storage device 954, loaded into memory device 956, and executed on processor 952. Alternatively, the control logic may be hard coded in the system controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
receiving a substrate in a process chamber, the substrate having one or more structures, each structure comprising a gap; and
performing a set of cycles of:
(a) exposing the substrate to one or more precursor species; and
(b) after (a), exposing the substrate to a plasma comprising one or more inhibition species and one or more co-reactants.

2. The method of claim 1, wherein the one or more inhibition species inhibits an adsorption of precursor species during a subsequent cycle.

3. The method of claim 1, wherein performing the set of cycles further comprises:
(c) after (b), exposing the substrate to a plasma comprising the one or more inhibition species without the one or more co-reactants.

4. The method of claim 1, wherein each cycle of the set of cycles has a duration less than about 7 seconds.

5. The method of claim 1, wherein each cycle of the set of cycles has a duration between about 2.5 seconds and about 5 seconds.

6. The method of claim 1, wherein the set of cycles consists essentially of (a) and (b).

7. The method of claim 1, wherein the one or more co-reactants comprise an oxygen-containing species.

8. The method of claim 1, wherein the one or more inhibition species comprise a nitrogen-containing species.

9. The method of claim 8, wherein the nitrogen-containing species is N₂, NH₃, or N₂O.

10. The method of claim 1, wherein the one or more inhibition species consists of a nitrogen-containing, non-halogen containing species.

11. The method of claim 1, wherein the one or more inhibition species inhibits near a top of the structures during (b).

12. The method of claim 11, wherein the one or more co-reactants reacts with the one or more precursor species during (b) to form a dielectric material.

13. The method of claim 12, wherein the dielectric material is an oxide material.

14. The method of claim 1, wherein performing the set of cycles further comprises purging the one or more precursor species from the process chamber between (a) and (b).

15. The method of claim 1, wherein performing the set of cycles fills the one or more structures from a bottom of the gap up.

16. A system, comprising:
a process chamber; and
one or more processors and one or more memories, the one or more memories comprising computer-executable instructions for controlling the one or more processors for:
receiving a substrate in the process chamber, the substrate having one or more structures, each structure comprising a gap; and
performing a set of cycles of:
(a) exposing the substrate to one or more precursor species; and
(b) after (a), exposing the substrate to a plasma comprising one or more inhibition species and one or more co-reactants.
